(19) United States
(12) Patent Application Publication
(10) Pub. No.: US 2013/0118541 A1
(43) Pub. Date: May 16, 2013

(54) THERMOELECTRIC MODULE AND METHOD OF MANUFACTURING THE SAME

(71) Applicant: Samsung Electro-Mechanics Co., Ltd., Suwon (KR)

(72) Inventors: Sung Ho LEE, Seongnam (KR); Ju Hwan YANG, Suwon (KR); Dong Hyeok CHOI, Suwon (KR); Kang Heon HUR, Seongnam (KR)

(73) Assignee: Samsung Electro-Mechanics Co., Ltd., Suwon (KR)

(21) Appl. No.: 13/673,407

(22) Filed: Nov. 9, 2012

(30) Foreign Application Priority Data
Nov. 11, 2011 (KR) 10-2011-0117765

(51) Int. Cl. H01L 35/32; H01L 35/34

(52) U.S. Cl. CPC H01L 35/325; H01L 35/34
USPC 136/200; 136/201

(57) ABSTRACT

Disclosed herein are a thermoelectric module and a method of manufacturing the same. The thermoelectric module includes: a thermoelectric laminate in which a plurality of N-type thermoelectric sheets made of an N-type thermoelectric material and a plurality of P-type thermoelectric sheets made of a P-type thermoelectric material are alternately disposed in a vertical direction and each of insulating sheets is provided between the N-type thermoelectric sheets and the P-type thermoelectric sheets; metal electrodes provided on left and right ends of the thermoelectric laminate; and substrates provided on outer side surfaces of the metal electrodes.

### CROSS REFERENCE(S) TO RELATED APPLICATIONS

This application claims the benefit under 35 U.S.C. Section 119 of Korean Patent Application Serial No. 10-2011-0117765, entitled “Thermoelectric Module And Method of Manufacturing the Same” filed on Nov. 11, 2011, which is hereby incorporated by reference in its entirety into this application.

### BACKGROUND OF THE INVENTION

1. Technical Field

The present invention relates to a thermoelectric module, and more particularly, to a thermoelectric module formed of a sheet type thermoelectric device.

2. Description of the Related Art

A thermoelectric device is a device using a Seebeck effect, which is a phenomenon that electromotive force is generated by a temperature difference present in the natural world and an artificial object such as a machine, a building, or the like, using thermoelectric conversion. Generally, in the thermoelectric device, heat or a carrier in a thermoelectric material moves in a vertical direction between facing surfaces of a low temperature region and a high temperature region as disclosed in US Patent Laid-Open Publication No. 2009-0025773.

Thermoelectric conversion is energy conversion between thermal energy and electric energy. This thermoelectric device has been mainly used in two applications such as power generation using the Seebeck effect that electricity is generated when a temperature difference is present at both ends of a thermoelectric material and cooling using a Peltier effect that a temperature gradient is generated between both ends of the thermoelectric material when current flows in the thermoelectric material.

When the Seebeck effect is used, heat generated from a computer, a vehicle engine, or the like may be converted into electric energy, and when the Peltier effect is used, various cooling systems that do not require a refrigerant may be implemented. Therefore, as the interest in development of new energy, recovery of waste energy, protection of environment, or the like, has recently increased, the interest in a thermoelectric device has increased.

FIG. 1 is a partially cut-away perspective view schematically showing a general thermoelectric device module according to the related art. Referring to FIG. 1, the thermoelectric device module according to the related art includes P-type thermoelectric materials 3 and N-type thermoelectric materials 5. Electrodes 9 having a predetermined pattern are attached to a pair of insulating substrates 7 made of ceramic or silicon nitride, such that the thermoelectric materials 3 and 5 are electrically connected in series with each other by the electrodes 9.

In the thermoelectric device module 1 according to the related art, when direct current voltage is applied to the electrodes 9 through the lead wire 4 connected to a terminal 2, heat is generated at a side in which the current flows from the P-type thermoelectric materials 3 to the N-type thermoelectric materials 5 and heat is absorbed at a side in which the current flows from the N-type thermoelectric materials 5 to the P-type thermoelectric materials 3 on the contrary, by the Peltier effect. Therefore, the insulating substrate 7 bonded to a heat generation side is heated, and the insulating substrate 7 bonded to a heat absorption side is cooled.

As described above, the thermoelectric device module according to the related art has a structure in which single modules including P-type thermoelectric devices and N-type thermoelectric devices are repeated in series with each other so as to be appropriate for a use condition. In addition, the respective single modules are connected to each other using a metal electrode, and the metal electrode is connected to a ceramic substrate.

The series type thermoelectric module structure as described above has a problem such as circuit disconnection and fatal danger that the entire complex module is not operated when a fault occurs only in one of the single modules.

In addition, since several processes should be performed at the time of manufacturing of the series type thermoelectric module, a manufacturing cost increases and reliability of a product is deteriorated.

### SUMMARY OF THE INVENTION

An object of the present invention is to provide a thermoelectric module formed of a sheet type thermoelectric device.

According an exemplary embodiment of the present invention, there is provided a thermoelectric module including: a thermoelectric laminate in which a plurality of N-type thermoelectric sheets made of an N-type thermoelectric material and a plurality of P-type thermoelectric sheets made of a P-type thermoelectric material are alternately disposed in a vertical direction and each of insulating sheets is provided between the N-type thermoelectric sheets and the P-type thermoelectric sheets; metal electrodes provided on left and right ends of the thermoelectric laminate; and substrates provided on outer side surfaces of the metal electrodes.

The N-type and P-type thermoelectric sheets may have roughness formed on upper and lower surfaces thereof.

The N-type and P-type thermoelectric sheets may have adhesives provided on upper and lower surfaces thereof.

The N-type and P-type thermoelectric materials may be at least one material selected from a group consisting of bismuth (Bi), antimony (Sb), tellurium (Te), and selenium (Se) or a mixture of at least two materials, and the insulating sheet may be made of at least one material selected from a group consisting of epoxy, polyimide, and polyamide or a mixture of at least two materials.

The N-type and P-type thermoelectric sheets may have a thickness of 1 to 100 μm.

The insulating sheet may have a thickness of 0.1 to 10 μm.

The insulating sheets may include protrusion parts formed by being partially protruded outside the N-type and P-type thermoelectric sheets, wherein the protrusion parts are positioned in an opposite direction to each other based on the N-type and P-type thermoelectric sheets.

According to another exemplary embodiment of the present invention, there is provided a method of manufacturing a thermoelectric module, the method including: (a) providing an N-type thermoelectric sheet, a P-type thermoelectric sheet, and an insulating sheet; (b) forming a thermoelectric laminate in which the plurality of N-type thermoelectric sheets and the plurality of P-type thermoelectric sheets are alternately disposed in a vertical direction and each of insulating sheets is provided between the N-type thermoelectric sheets and the P-type thermoelectric sheets; (c) forming metal electrodes on left and right ends of the thermoelectric laminate; and (d) providing substrates on outer side surfaces of the metal electrodes.

Each of the N-type thermoelectric sheet, the P-type thermoelectric sheet, and the insulating sheet provided in step (a) may be formed using an N-type thermoelectric slurry made of an N-type thermoelectric material, a P-type thermoelectric slurry made of a P-type thermoelectric material, and an insulating material slurry made of an insulating material.

The N-type and P-type thermoelectric materials may be at least one material selected from a group consisting of bismuth (Bi), antimony (Sb), tellurium (Te), and selenium (Se) or a mixture of at least two materials, and the insulating material may be at least one material selected from a group consisting of epoxy, polyimide, and polyamide or a mixture of at least two materials.

The method may further include pressing and firing the thermoelectric laminate formed in step (b).

The insulating sheets provided in step (a) may include protrusion parts formed by being partially protruded outside the N-type and P-type thermoelectric sheets, wherein the protrusion parts are positioned in an opposite direction to each other based on the N-type and P-type thermoelectric sheets.

A distance from end portions of the N-type and P-type thermoelectric sheets to the other surface of the metal electrode may be equal to or larger than a distance from the end portions of the N-type and P-type thermoelectric sheets to end portions of the protrusion parts.

The method may further include, after the metal electrodes are formed in step (c), cutting outer side surfaces of the metal electrodes formed on the left and right ends of the thermoelectric laminate so that the protrusion parts of the insulating sheets are exposed.

Step (c) may include: applying a metallic slurry to the left and right ends of the thermoelectric laminate; and curing the metallic slurry applied to the thermoelectric laminate.

Step (c) may include: immersing and then extracting the left end of the thermoelectric laminate in a container in which metallic pastes are contained; immersing and then extracting the right end of the thermoelectric laminate in the container in which the metallic pastes are contained; and curing the metallic pastes of the extracted thermoelectric laminate.

The method may further include, after step (a), forming roughness on upper and lower surfaces of the N-type and P-type thermoelectric sheets.

The method may further include, after step (a), providing adhesives on upper and lower surfaces of the N-type and P-type thermoelectric sheets.

The N-type and P-type thermoelectric sheets provided in step (a) may have a thickness of 1 to 100 μm.

The insulating sheet provided in step (a) may have a thickness of 0.1 to 10 μm.

### BRIEF DESCRIPTION OF THE DRAWINGS

FIG. 1 is a partially cut-away perspective view schematically showing a general thermoelectric device module according to the related art;

FIG. 2 shows a front view of a thermoelectric module according to an exemplary embodiment of the present invention;

FIG. 3 shows a perspective view of the thermoelectric module according to the exemplary embodiment of the present invention;

FIGS. 4A and 4B are views showing positions at which protrusion parts are formed; and

FIGS. 5A to 5E are process views sequentially showing a process of manufacturing a thermoelectric module according to the exemplary embodiment of the present invention.

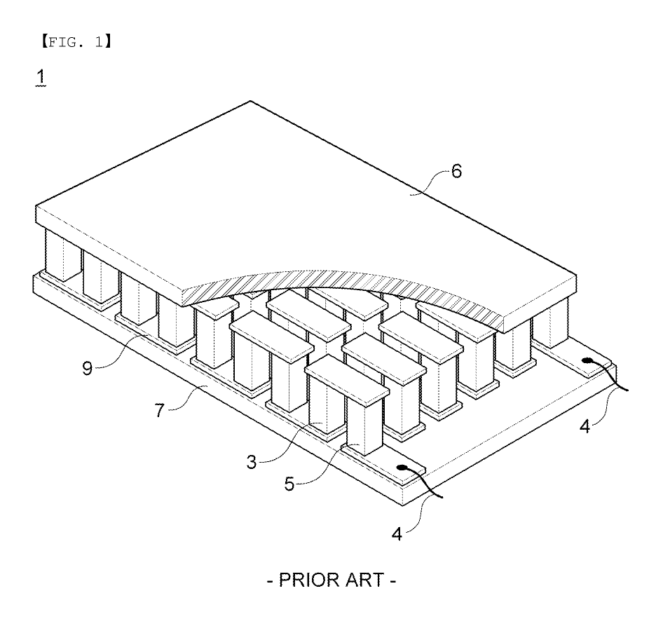

### DESCRIPTION OF THE PREFERRED EMBODIMENTS

Various advantages and features of the present invention and methods accomplishing thereof will become apparent from the following description of embodiments with reference to the accompanying drawings. However, the present invention may be modified in many different forms and it should not be limited to the embodiments set forth herein. These embodiments may be provided so that this disclosure will be thorough and complete, and will fully convey the scope of the invention to those skilled in the art. Like reference numerals throughout the description denote like elements.

In addition, terms used in the present specification are for explaining the embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

Hereinafter, a configuration and an acting effect of exemplary embodiments of the present invention will be described in more detail with reference to the accompanying drawings.

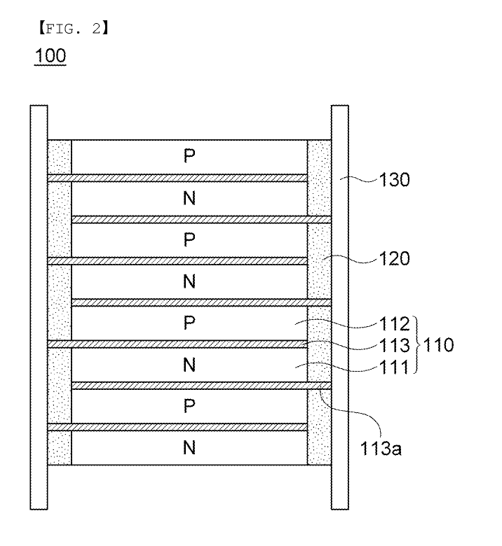

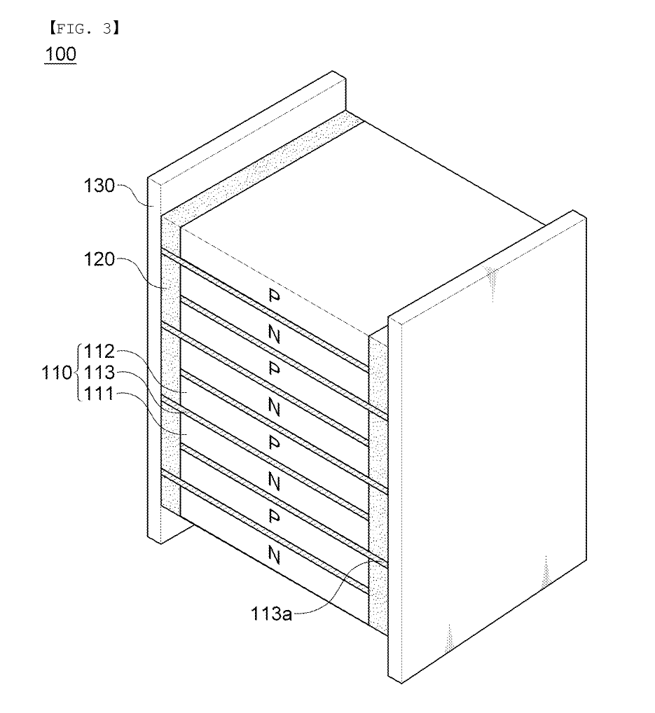

FIG. 2 shows a front view of a thermoelectric module 100 according to an exemplary embodiment of the present invention; and FIG. 3 shows a perspective view of the thermoelectric module 100 according to the exemplary embodiment of the present invention.

Referring to FIGS. 2 and 3, the thermoelectric module 100 according to the exemplary embodiment of the present invention may be configured to include a thermoelectric laminate 110 in which a plurality of N-type thermoelectric sheets 111 made of an N-type thermoelectric material and a plurality of P-type thermoelectric sheets 112 made of a P-type thermoelectric material are alternately disposed in a vertical direction and each of insulating sheets 113 is provided between the N-type thermoelectric sheets 111 and the P-type thermoelectric sheets 112; metal electrodes 120 provided on left and right ends of the thermoelectric laminate 110; and substrates 130 provided on outer side surfaces of the metal electrodes 120.

Here, each of the N-type thermoelectric sheet 111, the P-type thermoelectric sheet 112, and the insulating sheet 113 may be formed in a sheet type using an N-type thermoelectric slurry made of an N-type thermoelectric material, a P-type thermoelectric slurry made of a P-type thermoelectric material, and an insulating material slurry made of an insulating material.

The N-type and P-type thermoelectric materials may be at least one material selected from a group consisting of bismuth (Bi), antimony (Sb), tellurium (Te), and selenium (Se) or a mixture of at least two materials. In addition to the above-mentioned materials, the N-type and P-type thermoelectric materials may be other materials representing a thermoelectric effect in the art.

In addition, the insulating material may be at least one material selected from a group consisting of epoxy, polyimide, and polyamide or a mixture of at least two materials.

The insulating sheets 113 may include protrusion parts 113a formed by being partially protruded outside the N-type and P-type thermoelectric sheets 111 and 112, wherein the protrusion parts 113a may be positioned in an opposite direction to each other based on the thermoelectric sheets.

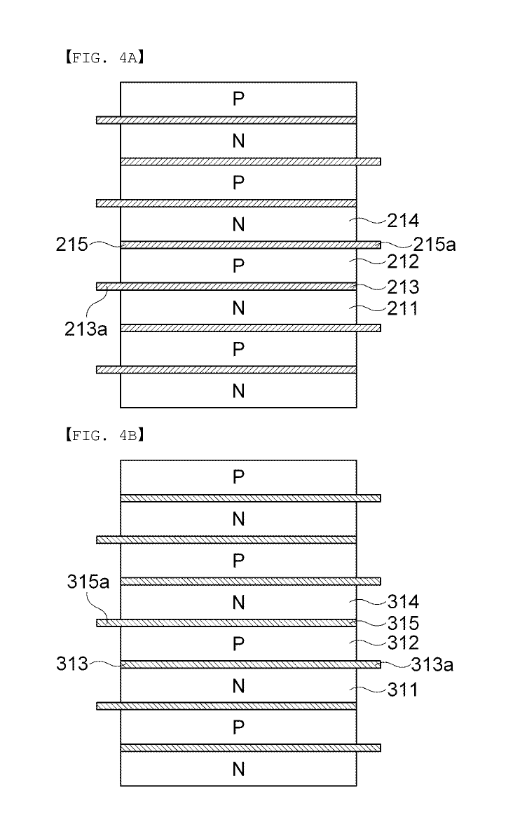

FIGS. 4A and 4B are views showing positions at which protrusion part 113a are formed. For example, as shown in FIG. 4A, a protrusion part 213a may be formed at a left portion of an insulating sheet 213 provided between an N-type thermoelectric sheet 211 and a P-type thermoelectric sheet 212 positioned directly over the N-type thermoelectric sheet 211, and a protrusion part 215a may be formed at a right portion of an insulating sheet 215 provided between the P-type thermoelectric sheet 212 and an N-type thermoelectric sheet 214 positioned directly over the P-type thermoelectric sheet 212.

Alternatively, as shown in FIG. 4B, a protrusion part 313a may be formed at a right portion of an insulating sheet 313 provided between an N-type thermoelectric sheet 311 and a P-type thermoelectric sheet 312 positioned directly over the N-type thermoelectric sheet 311, and a protrusion part 315a may be formed at a left portion of an insulating sheet 315 provided between the P-type thermoelectric sheet 312 and an N-type thermoelectric sheet 314 positioned directly over the P-type thermoelectric sheet 312.

Therefore, the insulating sheets 213, 215, 313, and 315 may prevent the N-type thermoelectric sheet and the P-type thermoelectric sheet from being directly short-circuited. At the same time, as shown in FIG. 4A, the protrusion part 213a provided at the left portion of the insulating sheet 213 may prevent a left portion of the N-type thermoelectric sheet 211 and a left portion of the P-type thermoelectric sheet 212 positioned directly over the N-type thermoelectric sheet 211 from being electrically short-circuited due to the metal electrode and the protrusion part 215a provided at the right portion of the insulating sheet 215 may prevent a right portion of the P-type thermoelectric sheet 212 and a right portion of the N-type thermoelectric sheet 214 positioned directly over the P-type thermoelectric sheet 212 from being electrically short-circuited due to the metal electrode.

Alternatively, as shown in FIG. 4B, the protrusion part 313a provided at the right portion of the insulating sheet 313 may prevent a right portion of the N-type thermoelectric sheet 311 and a right portion of the P-type thermoelectric sheet 312 positioned directly over the N-type thermoelectric sheet 311 from being electrically short-circuited due to the metal electrode and the protrusion part 315a provided at the left portion of the insulating sheet 315 may prevent a left portion of the P-type thermoelectric sheet 312 and a left portion of the N-type thermoelectric sheet 314 positioned directly over the P-type thermoelectric sheet 312 from being electrically short-circuited due to the metal electrode.

Meanwhile, in order to improve adhesion between the N-type thermoelectric sheet 111 and the insulating sheet 113 and between the P-type thermoelectric sheet 112 and the insulating sheet 113, roughness (not shown) may be formed on upper and lower surfaces of the N-type and P-type thermoelectric sheets 111 and 112 or adhesives (not shown) may be provided on the upper and lower surfaces of the N-type and P-type thermoelectric sheets 111 and 112.

The insulating sheet 113 may have a thickness in a range of 0.1 to 10 μm so as to perform only a minimum insulating function, and the N-type and P-type thermoelectric sheets 111 and 112 may have a thickness in a range of 1 to 100 μm so as to be formed in a sheet type to thereby improve productivity of a product, simultaneously with representing thermoelectric characteristics.

Hereinafter, a method of manufacturing a thermoelectric module 100 according to the exemplary embodiment of the present invention will be described.

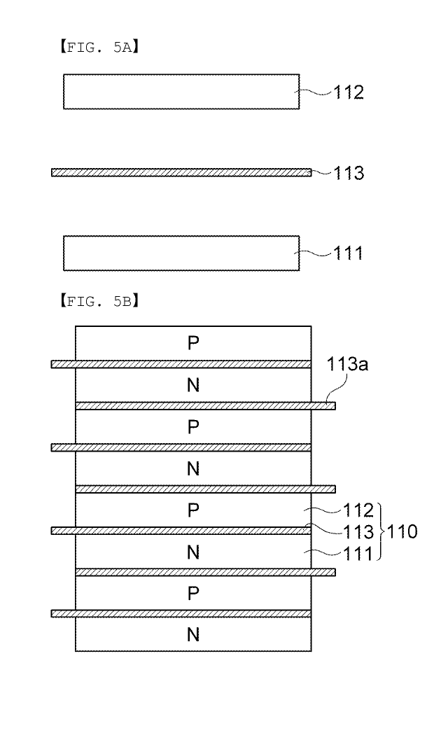

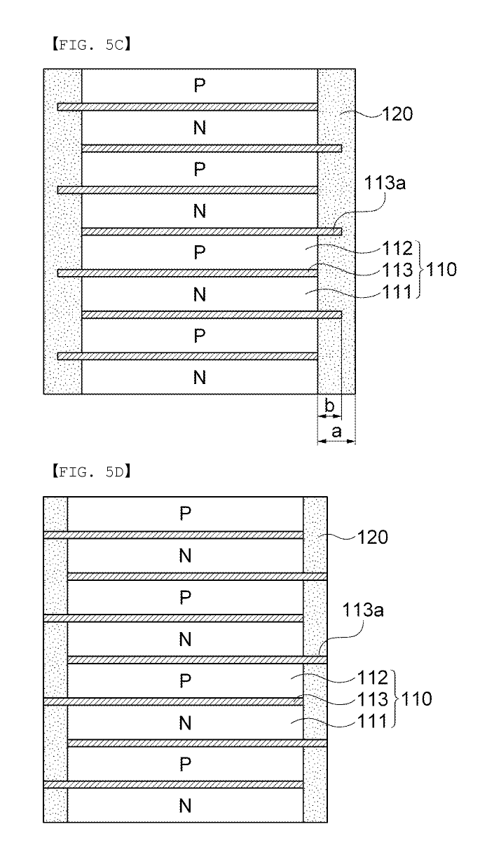

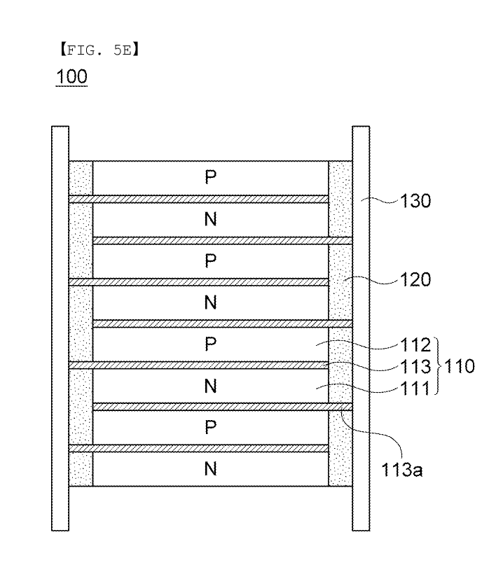

FIGS. 5A to 5E are process views sequentially showing a process of manufacturing a thermoelectric module according to the exemplary embodiment of the present invention.

Referring to FIG. 5, in the method of manufacturing the thermoelectric module 100 according to the exemplary embodiment of the present invention, an operation of providing an N-type thermoelectric sheet 111, a P-type thermoelectric sheet 112, and an insulating sheet 113 may be first performed as shown in FIG. 5A.

Here, each of the provided N-type thermoelectric sheet 111, P-type thermoelectric sheet 112, and insulating sheet 113 may be formed using an N-type thermoelectric slurry made of an N-type thermoelectric material, a P-type thermoelectric slurry made of a P-type thermoelectric material, and an insulating material slurry made of an insulating material.

The N-type and P-type thermoelectric materials may be at least one material selected from a group consisting of bismuth (Bi), antimony (Sb), tellurium (Te), and selenium (Se) or a mixture of at least two materials, and the insulating material may be at least one material selected from a group consisting of epoxy, polyimide, and polyamide or a mixture of at least two materials.

The provided insulating sheet 113 may include protrusion parts formed by being partially protruded outside the N-type and P-type thermoelectric sheets 111 and 112, wherein the protrusion parts may be positioned in an opposite direction to each other based on the thermoelectric sheets. Since a specific example thereof has been described above, a detailed description thereof will be omitted.

In addition, the insulating sheet 113 may have a thickness in a range of 0.1 to 10 μm so as to perform only a minimum insulating function, and the N-type and P-type thermoelectric sheets 111 and 112 may have a thickness in a range of 1 to 100 μm so as to be formed in a sheet type to thereby improve productivity of a product, simultaneously with representing thermoelectric characteristics.

Then, as shown in FIG. 5B, an operation of forming a thermoelectric laminate 110 in which a plurality of N-type thermoelectric sheets 111 and a plurality of P-type thermoelectric sheets 112 are alternately disposed in a vertical direction and each of insulating sheets 113 is provided between the N-type thermoelectric sheets 111 and the P-type thermoelectric sheets 112 may be performed.

At this time, an operation of bonding the N-type thermoelectric sheet 111, the P-type thermoelectric sheet 112, and the insulating sheet 113 to each other by pressing and firing the thermoelectric laminate 110 may be additionally performed.

Further, in order to improve adhesion between the N-type thermoelectric sheet 111 and the insulating sheet 113 and between the P-type thermoelectric sheet 112 and the insulating sheet 113, an operation of forming roughness on upper and lower surfaces of the N-type and P-type thermoelectric sheets 111 and 112 or an operation of providing adhesives on the upper and lower surfaces of the N-type and P-type thermoelectric sheets 111 and 112 may be additionally performed.

Next, as shown in FIG. 5C, an operation of forming metal electrodes 120 on left and right ends of the thermoelectric laminate 110 may be performed.

The metal electrodes 120 may be formed by applying a metallic slurry to the left and right ends of the thermoelectric laminate 110 and then curing the metallic slurry applied to the thermoelectric laminate 110.

Alternatively, the metal electrodes 120 may be formed by immersing and extracting the left end of the thermoelectric laminate 110 in a container in which metallic pastes are contained, immersing and extracting the right end of the thermoelectric laminate 110 in the container in which the metallic pastes are contained, and then curing the metallic pastes of the extracted thermoelectric laminate 110. Here, at the time of the extraction of the thermoelectric laminate 110, the thermoelectric laminate 110 may be covered by a cover so that the metallic pastes do not flow down.

In the thermoelectric module 100 according to the exemplary embodiment of the present invention having a sheet type lamination structure in the case of using the metal electrodes 120 through the above-mentioned operations, a process of manufacturing the metal electrodes 120 may be simplified, such that a product production cost may be reduced.

Further, the metal electrodes 120 may be more precisely formed as compared to a scheme of soldering a metal electrode in a case of manufacturing a thermoelectric module according to the related art, thereby making it possible to improve reliability of a product.

Meanwhile, in the case in which the metal electrodes 120 are formed through the above-mentioned operation, a distance a from end portions of the N-type and P-type thermoelectric sheets 111 and 112 to the other surface of the metal electrode 120 may be equal to or larger than a distance b from the end portions of the N-type and P-type thermoelectric sheets 111 and 112 to end portions of the protrusion parts 113a. Therefore, after the metal electrodes 120 are formed, an operation of cutting outer side surfaces of the metal electrodes 120 formed on the left and right ends of the thermoelectric laminate 110 by a predetermined amount so that the protrusion parts 113a of the insulating sheets 113 may be exposed.

Thereafter, as shown in FIG. 5E, an operation of providing substrates 130 on outer side surfaces of the metal electrodes 120 may be performed to thereby manufacture the thermoelectric module 100 according to the exemplary embodiment of the present invention.

As set forth above, with the thermoelectric module according to the exemplary embodiment of the present invention, the thermoelectric module having a sheet type lamination structure is implemented, thereby making it possible to improve productivity and reliability of a product as compared to the thermoelectric module according to the related art.

In addition, with the method of manufacturing a thermoelectric module according to the exemplary embodiment of the present invention, the metal electrodes are formed by immersing and extracting the thermoelectric laminate in the container in which the metallic pastes are contained, thereby making it possible to simplify a process of manufacturing the metal electrodes and thus reduce a product production cost. Further, the metal electrodes may be more precisely formed as compared to a scheme of soldering a metal electrode in a case of manufacturing a thermoelectric module according to the related art, thereby making it possible to improve reliability of a product.

The present invention has been described in connection with what is presently considered to be practical exemplary embodiments. Although the exemplary embodiments of the present invention have been described, the present invention may be also used in various other combinations, modifications and environments. In other words, the present invention may be changed or modified within the range of concept of the invention disclosed in the specification, the range equivalent to the disclosure and/or the range of the technology or knowledge in the field to which the present invention pertains. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed embodiments. It is to be understood that other embodiments are also included within the spirit and scope of the appended claims.

1. A thermoelectric module comprising:
a thermoelectric laminate in which a plurality of N-type thermoelectric sheets made of an N-type thermoelectric material and a plurality of P-type thermoelectric sheets made of a P-type thermoelectric material are alternately disposed in a vertical direction and each of insulating sheets is provided between the N-type thermoelectric sheets and the P-type thermoelectric sheets;
metal electrodes provided on left and right ends of the thermoelectric laminate; and
substrates provided on outer side surfaces of the metal electrodes.

2. The thermoelectric module according to claim 1, wherein the N-type and P-type thermoelectric sheets have roughness formed on upper and lower surfaces thereof.

3. The thermoelectric module according to claim 1, wherein the N-type and P-type thermoelectric sheets have adhesives provided on upper and lower surfaces thereof.

4. The thermoelectric module according to claim 1, wherein the N-type and P-type thermoelectric materials are at least one material selected from a group consisting of bismuth (Bi), antimony (Sb), tellurium (Te), and selenium (Se) or a mixture of at least two materials, and
the insulating sheet is made of at least one material selected from a group consisting of epoxy, polyimide, and polyamide or a mixture of at least two materials.

5. The thermoelectric module according to claim 1, wherein the N-type and P-type thermoelectric sheets have a thickness of 1 to 100 μm.

6. The thermoelectric module according to claim 1, wherein the insulating sheet has a thickness of 0.1 to 10 μm.

7. The thermoelectric module according to claim 1, wherein the insulating sheets include protrusion parts formed by being partially protruded outside the N-type and P-type thermoelectric sheets, the protrusion parts being positioned in an opposite direction to each other based on the N-type and P-type thermoelectric sheets.

8. A method of manufacturing a thermoelectric module, the method comprising:
providing an N-type thermoelectric sheet, a P-type thermoelectric sheet, and an insulating sheet;
forming a thermoelectric laminate in which a plurality of N-type thermoelectric sheets and a plurality of P-type thermoelectric sheets are alternately disposed in a vertical direction and each of insulating sheets is provided between the N-type thermoelectric sheets and the P-type thermoelectric sheets;
forming metal electrodes on left and right ends of the thermoelectric laminate; and
providing substrates on outer side surfaces of the metal electrodes.

9. The method according to claim 8, wherein each of the N-type thermoelectric sheet, the P-type thermoelectric sheet, and the insulating sheet provided in the providing the thermoelectric sheets and insulating sheet is formed using an N-type thermoelectric slurry made of an N-type thermoelectric material, a P-type thermoelectric slurry made of a P-type thermoelectric material, and an insulating material slurry made of an insulating material.

10. The method according to claim 9, wherein the N-type and P-type thermoelectric materials are at least one material selected from a group consisting of bismuth (Bi), antimony (Sb), tellurium (Te), and selenium (Se) or a mixture of at least two materials, and
the insulating material is at least one material selected from a group consisting of epoxy, polyimide, and polyamide or a mixture of at least two materials.

11. The method according to claim 8, further comprising pressing and firing the thermoelectric laminate formed in the forming a thermoelectric laminate.

12. The method according to claim 8, wherein the forming metal electrodes includes:
applying a metallic slurry to the left and right ends of the thermoelectric laminate; and
curing the metallic slurry applied to the thermoelectric laminate.

13. The method according to claim 8, wherein the forming metal electrodes includes:
immersing the left end of the thermoelectric laminate in a container in which metallic pastes are contained;
immersing the right end of the thermoelectric laminate in the container in which the metallic pastes are contained; and
curing the metallic pastes of the thermoelectric laminate.

14. The method according to claim 8, wherein the insulating sheets provided in the providing the thermoelectric sheets and insulating sheet include protrusion parts formed by being partially protruded outside the N-type and P-type thermoelectric sheets, the protrusion parts being positioned in an opposite direction to each other based on the N-type and P-type thermoelectric sheets.

15. The method according to claim 14, wherein a distance from end portions of the N-type and P-type thermoelectric sheets to the other surface of the metal electrode is equal to or larger than a distance from the end portions of the N-type and P-type thermoelectric sheets to end portions of the protrusion parts.

16. The method according to claim 15, further comprising, after the metal electrodes are formed in the forming metal electrodes, cutting outer side surfaces of the metal electrodes formed on the left and right ends of the thermoelectric laminate so that the protrusion parts of the insulating sheets are exposed.

17. The method according to claim 8, further comprising, after the providing the thermoelectric sheets and insulating sheet, forming roughness on upper and lower surfaces of the N-type and P-type thermoelectric sheets.

18. The method according to claim 8, further comprising, after the providing the thermoelectric sheets and insulating sheet, providing adhesives on upper and lower surfaces of the N-type and P-type thermoelectric sheets.

19. The method according to claim 8, wherein the N-type and P-type thermoelectric sheets provided in the providing the thermoelectric sheets and insulating sheet have a thickness of 1 to 100 μm.

20. The method according to claim 8, wherein the insulating sheet provided in the providing the thermoelectric sheets and insulating sheet has a thickness of 0.1 to 10 μm.
